(19) United States
(12) Patent Application Publication
(10) Pub. No.: US 2014/0111913 A1
(43) Pub. Date: Apr. 24, 2014

(54) PROTECTION STRUCTURE APPLIED TO A HAND-HELD ELECTRONIC DEVICE

(71) Applicant: COOLER MASTER CO., LTD., New Taipei City (TW)

(72) Inventors: SHU-HAO LIU, NEW TAIPEI CITY (TW); JHIH-WEI RAO, NEW TAIPEI CITY (TW)

(73) Assignee: COOLER MASTER CO., LTD., NEW TAIPEI CITY (TW)

(21) Appl. No.: 13/656,673

(22) Filed: Oct. 20, 2012

(51) Int. Cl. H05K 5/03

(52) U.S. Cl. 361/679.01

(57) ABSTRACT

A protection structure applied to a hand-held electronic device includes a protection unit and a connection unit. The protection unit includes at least one first protection frame and at least one second protection frame, and the hand-held electronic device is placed between the first protection frame and the second protection frame. The connection unit includes at least one connection element slidably disposed between the first protection frame and the second protection frame. Therefore, the first protection frame and the second protection frame can be firmly positioned on a front surrounding edge and a rear surrounding edge of the hand-held electronic device for protecting the hand-held electronic device through the connection element.

### BACKGROUND OF THE INVENTION

1. Field of the Invention

The instant disclosure relates to a protection structure, and more particularly to a protection structure applied to a hand-held electronic device.

2. Description of Related Art

Portable electronic devices, such as a mobile phone, a media player, and a personal digital assistant (PDA) are increasingly thinner and smaller. However, the portable electronic device is damaged or abraded easily when it bumps against other objects.

### SUMMARY OF THE INVENTION

One aspect of the instant disclosure relates to a protection structure applied to a hand-held electronic device.

One of the embodiments of the instant disclosure provides a protection structure applied to a hand-held electronic device, the hand-held electronic device has a front surface, a rear surface opposite to the front surface, a surrounding peripheral surface disposed between the front surface and the rear surface, a front surrounding edge connected between the front surface and the surrounding peripheral surface, and a rear surrounding edge connected between the rear surface and the surrounding peripheral surface, wherein the protection structure comprises: a protection unit and a connection unit. The protection unit includes at least one first protection frame corresponding to the front surrounding edge of the hand-held electronic device and at least one second protection frame corresponding to the rear surrounding edge of the hand-held electronic device, wherein the hand-held electronic device is placed between the at least one first protection frame and the at least one second protection frame, the at least one first protection frame has at least two first upper retaining structures, and the at least one second protection frame has at least two second upper retaining structures respectively corresponding to the at least two first upper retaining structures. The connection unit includes at least one connection element slidably disposed between the at least one first protection frame and the at least one second protection frame, wherein the at least one first protection frame and the at least one second protection frame are respectively positioned on the front surrounding edge and the rear surrounding edge of the hand-held electronic device through the at least one connection element, and the at least one connection element has at least two first front retaining structures respectively retainingly mated with the at least two first upper retaining structures and at least two first rear retaining structures respectively retainingly mated with the at least two second upper retaining structures.

Another one of the embodiments of the instant disclosure provides a protection structure applied to a hand-held electronic device, comprising: a protection unit and a connection unit. The protection unit includes at least one first protection frame and at least one second protection frame, wherein the hand-held electronic device is placed between the at least one first protection frame and the at least one second protection frame. The connection unit includes at least one connection element slidably disposed between the at least one first protection frame and the at least one second protection frame, wherein the at least one first protection frame and the at least one second protection frame are positioned on the hand-held electronic device through the at least one connection element.

More precisely, the protection unit includes at least one first surrounding buffer pad disposed between an inner edge of the at least one first protection frame and the front surrounding edge of the hand-held electronic device and at least one second surrounding buffer pad disposed between an inner edge of the at least one second protection frame and the rear surrounding edge of the hand-held electronic device, the at least one first protection frame is separated from the hand-held electronic device by a first predetermined distance through the at least one first surrounding buffer pad, and the at least one second protection frame is separated from the hand-held electronic device by a second predetermined distance through the at least one second surrounding buffer pad. Hence, when the hand-held electronic device is fell on the floor or impacted by any solid object, the first surrounding buffer pad and the second surrounding buffer pad can be mated with each other to provide a buffer effect to cushion the damage that is caused when the hand-held electronic device impacted. In other words, the hand-held electronic device can obtain an optimal protection effect by matching the first protection frame having the first surrounding buffer pad and the second protection frame having the second surrounding buffer pad.

Therefore, the at least one first protection frame and the at least one second protection frame can be respectively firmly positioned on the front surrounding edge and the rear surrounding edge of the hand-held electronic device for protecting the hand-held electronic device through the at least one connection element that is slidably disposed between the at least one first protection frame and the at least one second protection frame.

To further understand the techniques, means and effects of the instant disclosure applied for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention to limit the instant disclosure.

### BRIEF DESCRIPTION OF THE DRAWINGS

FIG. 1A shows an exploded, schematic view of the protection structure applied to a hand-held electronic device according to the first embodiment of the instant disclosure;

FIG. 1B shows a partial, assembled, schematic view of the protection structure applied to a hand-held electronic device according to the first embodiment of the instant disclosure;

FIG. 1C shows an assembled, schematic view of the protection structure applied to a hand-held electronic device according to the first embodiment of the instant disclosure;

FIG. 2 shows a perspective, exploded, schematic view of the first protection frame and the first surrounding buffer pad of the protection structure according to the first embodiment of the instant disclosure;

FIG. 3 shows a perspective, exploded, schematic view of the second protection frame and the second surrounding buffer pad of the protection structure according to the first embodiment of the instant disclosure;

FIG. 4 shows a perspective, schematic view of the connection element of the protection structure according to the first embodiment of the instant disclosure;

FIG. 5 shows another perspective, schematic view of the first-type connection element of the protection structure according to the first embodiment of the instant disclosure;

FIG. 6A shows a front, exploded, schematic view of the second-type connection element of the protection structure according to the first embodiment of the instant disclosure;

FIG. 6B shows a front, exploded, schematic view of the third-type connection element of the protection structure according to the first embodiment of the instant disclosure;

FIG. 6C shows a front, exploded, schematic view of the fourth-type connection element of the protection structure according to the first embodiment of the instant disclosure;

FIG. 6D shows a front, exploded, schematic view of the fifth-type connection element of the protection structure according to the first embodiment of the instant disclosure;

FIG. 7A shows a front, exploded, schematic view of the protection structure applied to a hand-held electronic device according to the second embodiment of the instant disclosure;

FIG. 7B shows a front, assembled, schematic view of the protection structure applied to a hand-held electronic device according to the second embodiment of the instant disclosure;

FIG. 8 shows a top, schematic view of the protection structure using a first auxiliary retaining structure and a second auxiliary retaining structure according to the third embodiment of the instant disclosure; and

FIG. 9 shows a top, schematic view of the protection structure using another first auxiliary retaining structure and another second auxiliary retaining structure according to the third embodiment of the instant disclosure.

### DETAILED DESCRIPTION OF THE PREFERRED EMBODIMENTS

### First Embodiment

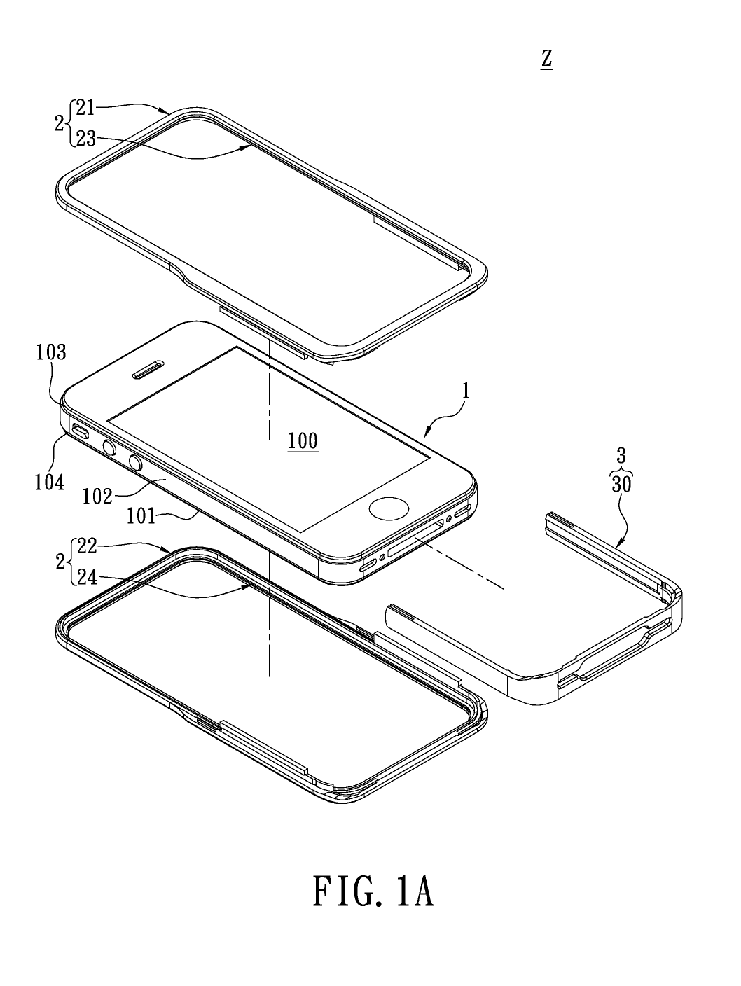

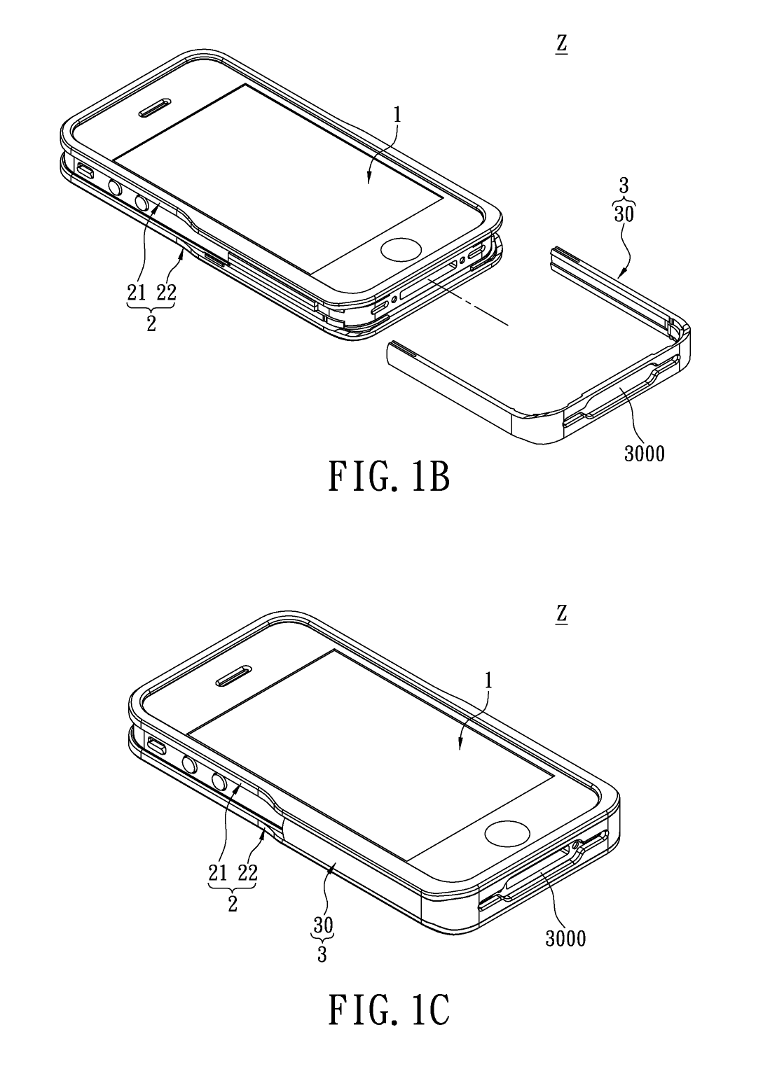

Referring to FIG. 1A to FIG. 1C, where the first embodiment of the instant disclosure provides a protection structure Z applied to a hand-held electronic device 1. The hand-held electronic device 1 has a front surface 100, a rear surface 101 opposite to the front surface 100, a surrounding peripheral surface 102 disposed between the front surface 100 and the rear surface 101, a front surrounding edge 103 connected between the front surface 100 and the surrounding peripheral surface 102, and a rear surrounding edge 104 connected between the rear surface 101 and the surrounding peripheral surface 102, and the protection structure Z comprises a protection unit 2 and a connection unit 3. Moreover, the protection unit 2 includes at least one first protection frame 21 corresponding to the front surrounding edge 103 of the hand-held electronic device 1 and at least one second protection frame 22 corresponding to the rear surrounding edge 104 of the hand-held electronic device 1, and the hand-held electronic device 1 can be placed between the first protection frame 21 and the second protection frame 22, thus the first protection frame 21 and the second protection frame 22 can help to cushion the damage that is caused when the hand-held electronic device 1 impacted. In addition, the connection unit 3 includes at least one connection element 30 (such as a connection piece) slidably disposed between the first protection frame 21 and the second protection frame 22, and the first protection frame 21 and the second protection frame 22 can be positioned on the hand-held electronic device 1 through the connection element 30.

For example, when a user wants to use the protection structure Z to protect the hand-held electronic device 1 (such as any smart mobile phone having a touch-controlled function), the hand-held electronic device 1 can be placed between the first protection frame 21 and the second protection frame 22 in advance (as shown in FIG. 1A and FIG. 1B), and then the connection element 30 can be retainingly connected between the first protection frame 21 and the second protection frame 22 by sliding (as shown in FIG. 1B and FIG. 1C). Hence, the first protection frame 21 and the second protection frame 22 can be firmly positioned on the front surrounding edge 103 and the rear surrounding edge 104 of the hand-held electronic device 1 through the connection and the retaining functions of the connection element 30, respectively.

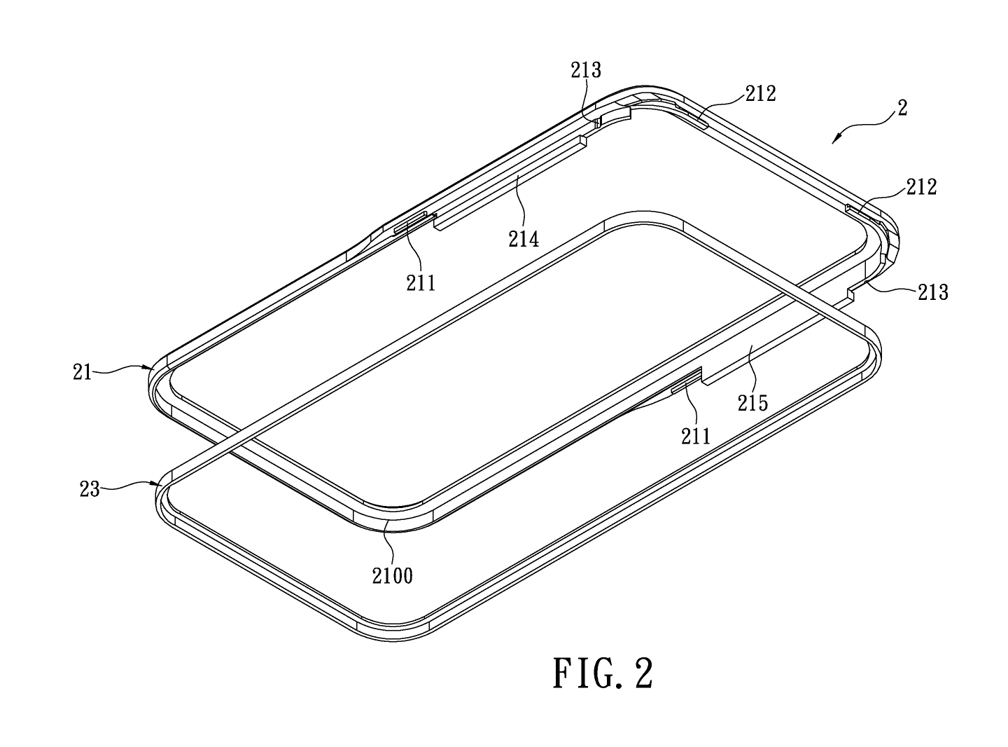

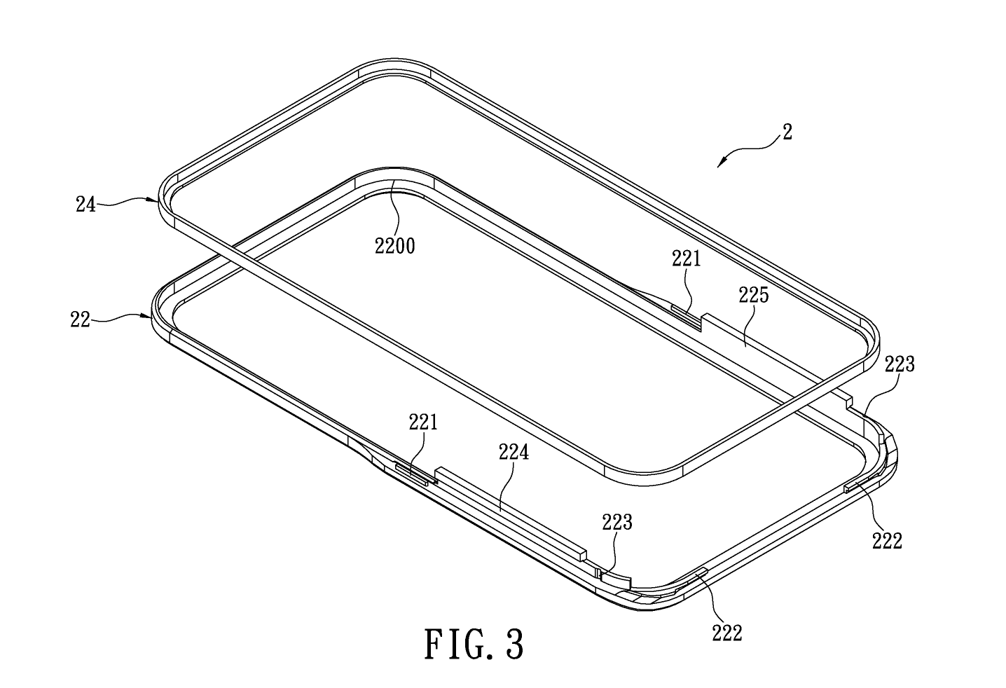

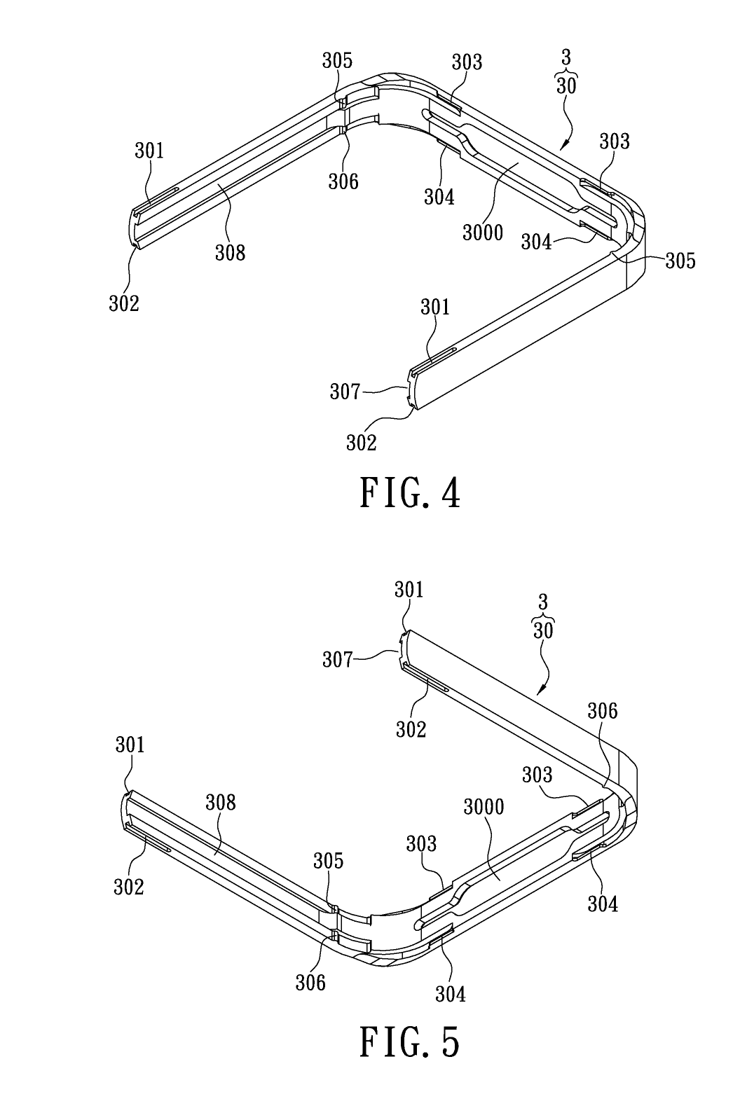

Furthermore, referring to FIG. 1A and FIG. 2 to FIG. 5, the protection unit 2 can further include at least one first surrounding buffer pad 23 disposed between an inner edge 2100 of the first protection frame 21 and the front surrounding edge 103 of the hand-held electronic device 1 and at least one second surrounding buffer pad 24 disposed between an inner edge 2200 of the second protection frame 22 and the rear surrounding edge 104 of the hand-held electronic device 1, and both the first surrounding buffer pad 23 and the second surrounding buffer pad 24 may be continuous surrounding cushioning pads. More precisely, the first protection frame 21 can be separated from the hand-held electronic device 1 by a first predetermined distance through the first surrounding buffer pad 23, and the second protection frame 22 can be separated from the hand-held electronic device 1 by a second predetermined distance through the second surrounding buffer pad 24.

Therefore, when the hand-held electronic device 1 is fell on the floor or impacted by any solid object, the first surrounding buffer pad 23 and the second surrounding buffer pad 24 can be mated with each other to provide a buffer effect to cushion the damage that is caused when the hand-held electronic device 1 impacted. In other words, the hand-held electronic device 1 can obtain an optimal protection effect by matching the first protection frame 21 having the first surrounding buffer pad 23 and the second protection frame 22 having the second surrounding buffer pad 24. In addition, when the first protection frame 21 and the second protection frame 22 are made of metal material, the first protection frame 21 and the second protection frame 22 can be insulated from the hand-held electronic device 1 through the first surrounding buffer pad 23 and the second surrounding buffer pad 24 to maintain the mobile phone communication effect of the hand-held electronic device 1.

Moreover, referring to FIG. 1A and FIG. 2 to FIG. 5, the first protection frame 21 has at least two first upper retaining structures 211, and the second protection frame 22 has at least two second upper retaining structures 221 respectively corresponding to the at least two first upper retaining structures 211, and the connection element 30 has at least two first front retaining structures 301 respectively retainingly mated with the at least two first upper retaining structures 211 and at least two first rear retaining structures 302 respectively retainingly mated with the at least two second upper retaining structures 221. More precisely, each first upper retaining structure 211 may be a first retaining block and each first front retaining structure 301 may be a front retaining groove for receiving the first retaining block, and each second upper retaining structure 221 may be a second retaining block and each first rear retaining structure 302 may be a rear retaining groove for receiving the second retaining block.

In addition, referring to FIG. 1A to FIG. 1C and FIG. 2 to FIG. 5, the first protection frame 21 has at least two first lower retaining structures 212, the second protection frame 22 has at least two second lower retaining structures 222 respectively corresponding to the at least two first lower retaining structures 212, and the connection element 30 has at least two second front retaining structures 303 respectively retainingly mated with the at least two first lower retaining structures 212 and at least two second rear retaining structures 304 respectively retainingly mated with the at least two second lower retaining structures 222. More precisely, the at least two first upper retaining structures 211 can be respectively disposed on two opposite lateral sides of the first protection frame 21, and the at least two second upper retaining structures 221 can be respectively disposed on two opposite lateral sides of the second protection frame 22. Moreover, the at least two first lower retaining structures 212 can be disposed on the bottom side of the first protection frame 21, and the at least two second lower retaining structures 222 can be disposed on the bottom side of the second protection frame 22. For example, each first lower retaining structure 212 has a retaining body and a retaining groove adjacent to the retaining body, and each second front retaining structure 303 has a retaining groove and a retaining body adjacent to the retaining groove. Hence, when the connection element 30 is retainingly connected between the first protection frame 21 and the second protection frame 22 by sliding (as shown in FIG. 1C), the retaining body of each first lower retaining structure 212 can be inserted into the retaining groove of each second front retaining structure 303, and the retaining body of each second front retaining structure 303 can be inserted into the retaining groove of each first lower retaining structure 212, thus the first lower retaining structure 212 and the second front retaining structure 303 can be retainingly mated with each other. According to the same design principle, each second lower retaining structure 222 has a retaining body and a retaining groove adjacent to the retaining body, and each second rear retaining structure 304 has a retaining groove and a retaining body adjacent to the retaining groove. Hence, when the connection element 30 is retainingly connected between the first protection frame 21 and the second protection frame 22 by sliding (as shown in FIG. 1C), the retaining body of each second lower retaining structure 222 can be inserted into the retaining groove of each second rear retaining structure 304, and the retaining body of each second rear retaining structure 304 can be inserted into the retaining groove of each second lower retaining structure 222, thus the second lower retaining structure 222 and the second rear retaining structure 304 can be retainingly mated with each other.

Furthermore, referring to FIG. 1A to FIG. 1C and FIG. 2 to FIG. 5, the first protection frame 21 has at least two first positioning grooves 213, the second protection frame 22 has at least two second positioning grooves 223, and the connection element 30 has at least two front positioning protrusions 305 respectively positioned in the at least two first positioning grooves 213 and at least two rear positioning protrusions 306 respectively positioned in the at least two positioning grooves 223. More precisely, when the connection element 30 is retainingly connected between the first protection frame 21 and the second protection frame 22 by sliding (as shown in FIG. 1C), the at least two front positioning protrusions 305 can be respectively positioned in the at least two first positioning grooves 213, and the at least two rear positioning protrusions 306 can be respectively positioned in the at least two positioning grooves 223, thus the first protection frame 21 and the second protection frame 22 can be accurately positioned on the front surrounding edge 103 and the rear surrounding edge 104 of the hand-held electronic device 1 through the connection element 30, respectively.

Besides, referring to FIG. 1A to FIG. 1C and FIG. 2 to FIG. 5, the first protection frame 21 has at least one first left-sided sliding track 214 and at least one first right-sided sliding track 215, the second protection frame 22 has at least one second left-sided sliding track 224 corresponding to the first left-sided sliding track 214 and at least one second right-sided sliding track 225 corresponding to the first right-sided sliding track 215, and the connection element 30 has at least one left-sided sliding groove 307 for concurrently receiving the first left-sided sliding track 214 and the second left-sided sliding track 224 and at least one right-sided sliding groove 308 for concurrently receiving the first right-sided sliding track 215 and the second right-sided sliding track 225. More precisely, when the first protection frame 21 and the second protection frame 22 are respectively positioned on two opposite surrounding edges (i.e., the front surrounding edge 103 and the rear surrounding edge 104) of the hand-held electronic device 1 (as shown in FIG. 1C), the first left-sided sliding track 214 and the second left-sided sliding track 224 can be contacted with each other to form a left-sided combined sliding track, and the first right-sided sliding track 215 and the second right-sided sliding track 225 can be contacted with each other to form a right-sided combined sliding track. Therefore, the connection element 30 can be slidably retained between the first protection frame 21 and the second protection frame 22 by slidably matching the left-sided sliding groove 307 and the left-sided combined sliding track (i.e., the first left-sided sliding track 214 and the second left-sided sliding track 224) and slidably matching the right-sided sliding groove 308 and right-sided combined sliding track (i.e., the first right-sided sliding track 215 and the second right-sided sliding track 225), thus the first protection frame 21 and the second protection frame 22 can be firmly positioned on the front surrounding edge 103 and the rear surrounding edge 104 of the hand-held electronic device 1 through the connection element 30, respectively.

In addition, referring to FIG. 1B to FIG. 1C and FIG. 4 to FIG. 5, the connection element 30 shown as a U-shaped piece, and the connection element 30 has at least one through opening 3000 passing through the bottom side thereof for exposing a bottom portion of the hand-held electronic device 1 to prevent the connector on the bottom portion of the hand-held electronic device 1 from being covered by the connection element 30.

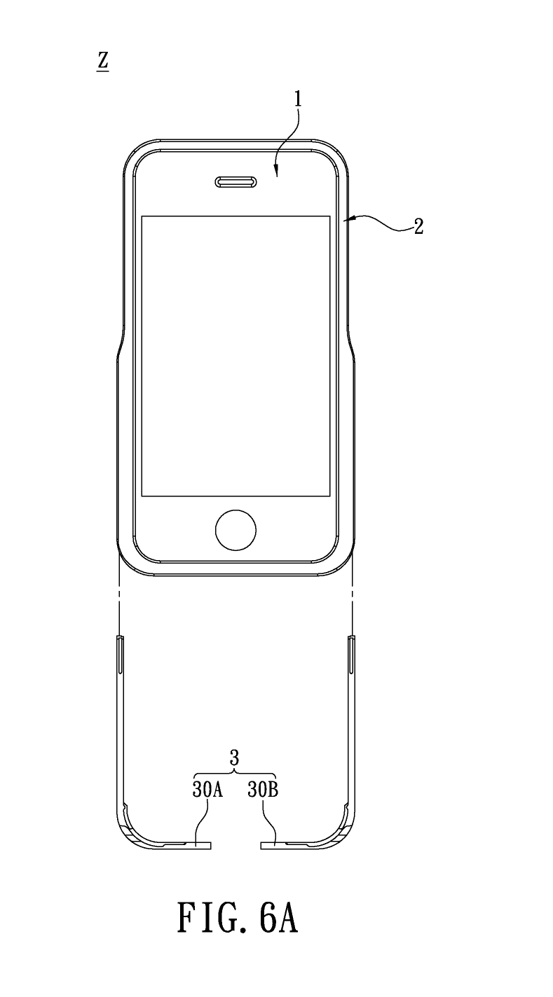

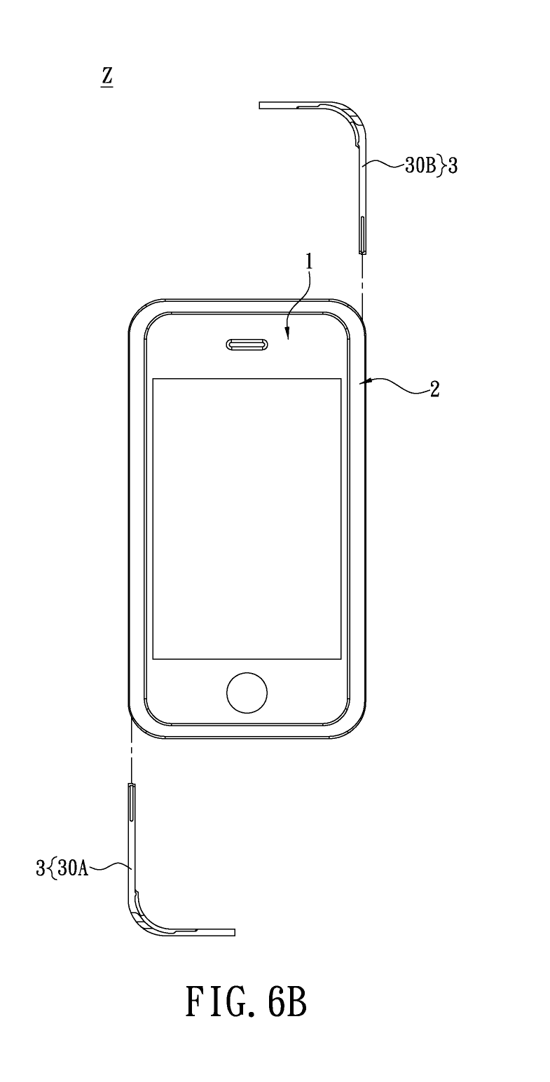

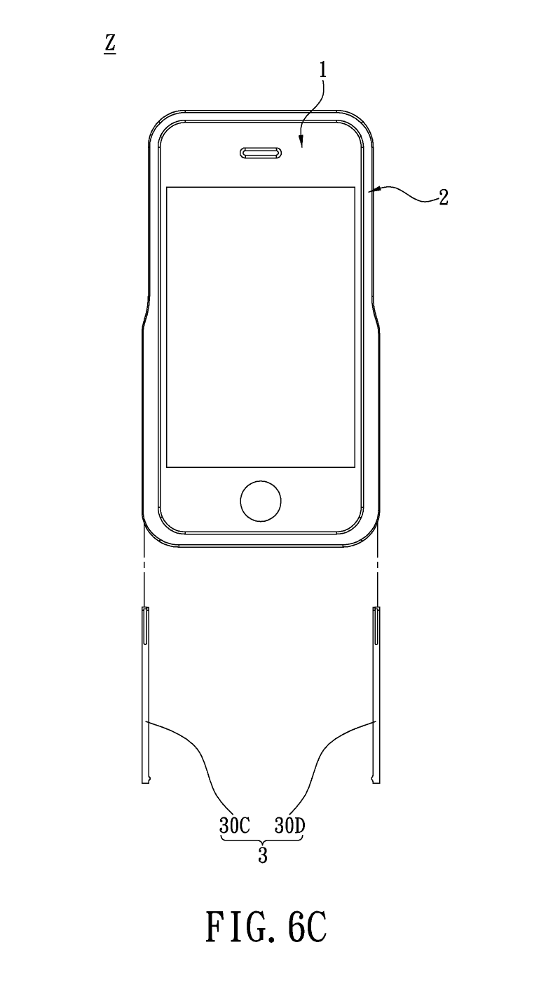

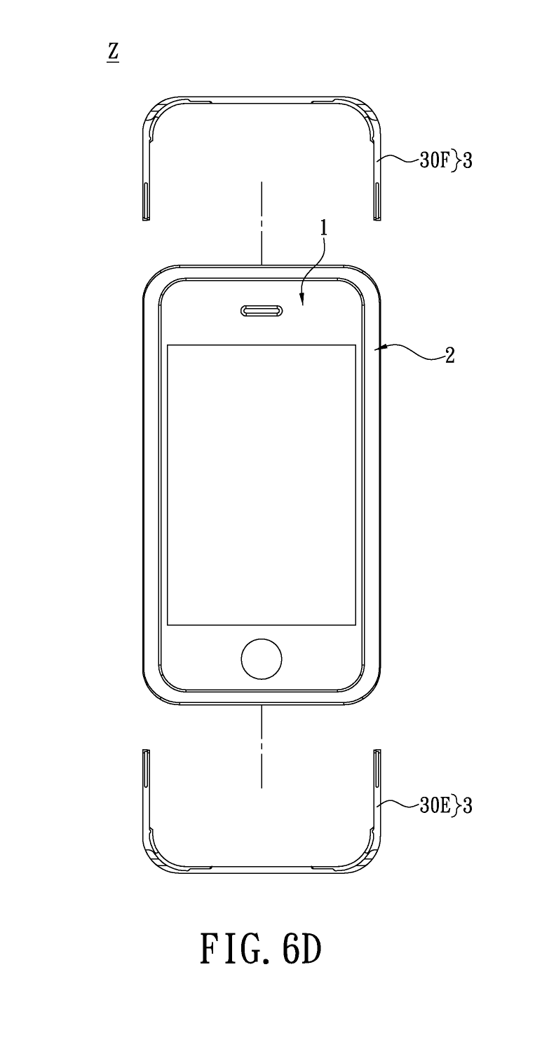

Moreover, referring to FIG. 1A, FIG. 6A and FIG. 6B, the U-shaped connection element 30 as shown in FIG. 1A can be replaced by two L-shaped connection elements (30A, 30B) as shown in FIG. 6A and FIG. 6B. Hence, referring to FIG. 6A, when the two L-shaped connection elements (30A, 30B) are moved from the bottom portion of the hand-held electronic device 1 to the position between the first protection frame 21 and the second protection frame 22, the first protection frame 21 and the second protection frame 22 also can be firmly positioned on the front surrounding edge 103 and the rear surrounding edge 104 of the hand-held electronic device 1 through the two L-shaped connection elements (30A, 30B), respectively. In addition, referring to FIG. 6B, when the two L-shaped connection elements (30A, 30B) are respectively moved from the bottom portion and the top portion of the hand-held electronic device 1 to the position between the first protection frame 21 and the second protection frame 22, the first protection frame 21 and the second protection frame 22 also can be firmly positioned on the front surrounding edge 103 and the rear surrounding edge 104 of the hand-held electronic device 1 through the two L-shaped connection elements (30A, 30B), respectively.

Furthermore, referring to FIG. 1A and FIG. 6C, the U-shaped connection element 30 as shown in FIG. 1A can be replaced by two horizontal connection elements (30C, 30D) as shown in FIG. 6C. Hence, when the two horizontal connection elements (30C, 30D) are moved from the bottom portion of the hand-held electronic device 1 to the position between the first protection frame 21 and the second protection frame 22, the first protection frame 21 and the second protection frame 22 also can be firmly positioned on the front surrounding edge 103 and the rear surrounding edge 104 of the hand-held electronic device 1 through the two horizontal connection elements (30C, 30D), respectively.

Besides, referring to FIG. 1A and FIG. 6D, the U-shaped connection element 30 as shown in FIG. 1A can be replaced by two U-shaped connection elements (30E, 30F) as shown in FIG. 6D. Hence, when the two U-shaped connection elements (30E, 30F) are respectively moved from the bottom portion and the top portion of the hand-held electronic device 1 to the position between the first protection frame 21 and the second protection frame 22, the first protection frame 21 and the second protection frame 22 also can be firmly positioned on the front surrounding edge 103 and the rear surrounding edge 104 of the hand-held electronic device 1 through the two U-shaped connection elements (30E, 30F), respectively.

### Second Embodiment

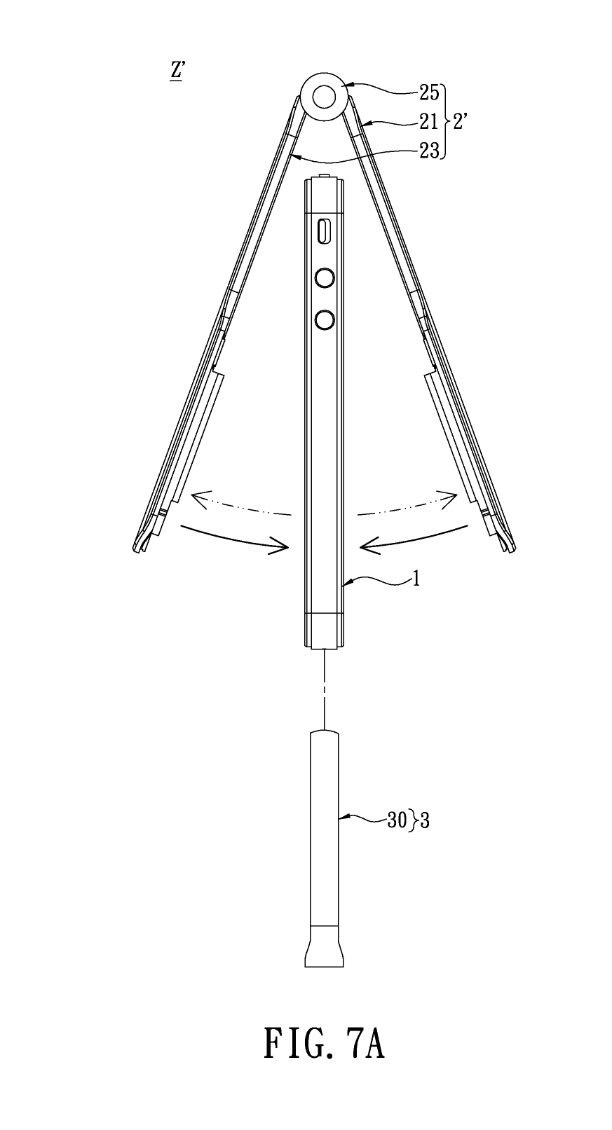

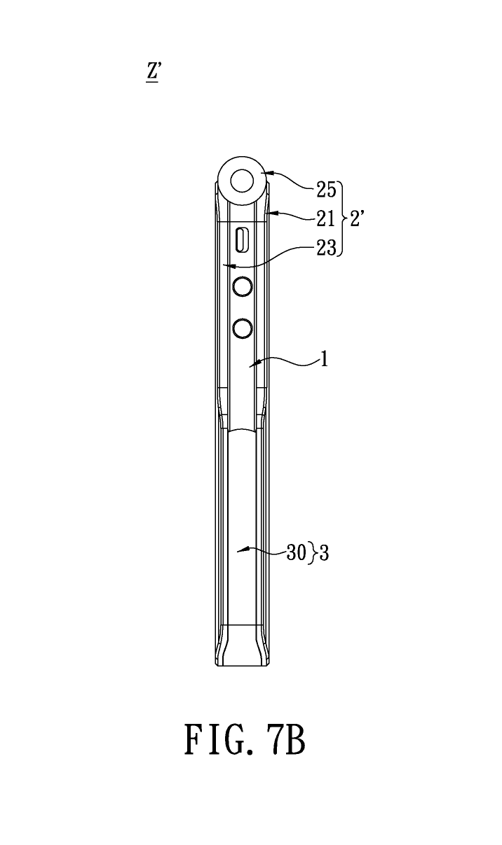

Referring to FIG. 7A and FIG. 7B, where the second embodiment of the instant disclosure provides a protection structure Z′ applied to a hand-held electronic device 1, and the protection structure Z′ comprises a protection unit 2′ and a connection unit 3. Comparing FIG. 7A with FIG. 1A and comparing FIG. 7B with FIG. 1C, the difference between the second embodiment and the first embodiment is as follows: in the second embodiment, the protection unit 2′ includes at least one pivot structure 25 connected between a top portion of the first protection frame 21 and a top portion of the second protection frame 22, and the connection unit 3 includes at least one connection element 30 connected between a bottom portion of the first protection frame 21 and a bottom portion of the second protection frame 22. More precisely, the first protection frame 21 and the second protection frame 22 can be separated from each other (i.e., the opening action shown as the dotted line arrow in FIG. 7A) or contacted with each other (i.e., the closing action shown as the solid line arrow in FIG. 7A) through the pivot structure 25 connected between the top portion of the first protection frame 21 and the top portion of the second protection frame 22. For example, the hand-held electronic device 1 can be placed on the first protection frame 21 in advance, next the second protection frame 22 can be rotated relative to the pivot structure 25 to cover the hand-held electronic device 1, and then the connection element 30 can be retainingly disposed between the first protection frame 21 and the second protection frame 22 by sliding (as shown in FIG. 7B), thus the first protection frame 21 and the second protection frame 22 can be firmly positioned on the front surrounding edge 103 and the rear surrounding edge 104 of the hand-held electronic device 1 through the connection element 30, respectively.

### Third Embodiment

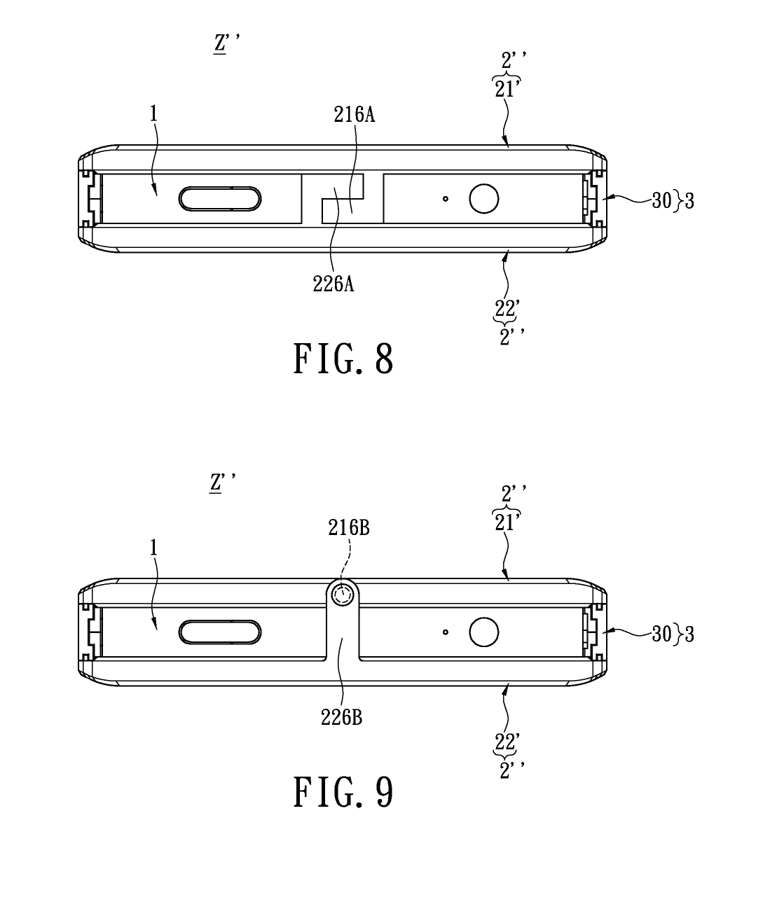

Referring to FIG. 8 and FIG. 9, where the third embodiment of the instant disclosure provides a protection structure Z″ applied to a hand-held electronic device 1, and the protection structure Z″ comprises a protection unit 2″ and a connection unit 3. Comparing FIG. 8 with FIG. 1A and comparing FIG. 9 with FIG. 1A, the difference between the third embodiment and the first embodiment is as follows: in the third embodiment, the first protection frame 21′ further has at least one first auxiliary retaining structure (216A, 216B), and the second protection frame 22′ has at least one second auxiliary retaining structure (226A, 226B) retainingly mated with the first auxiliary retaining structure (216A, 216B). More precisely, the first auxiliary retaining structure (216A, 216B) is disposed on a top portion of the first protection frame 21′, the second auxiliary retaining structure (226A, 226B) is disposed on a top portion of the second protection frame 22′, and the connection element 30 is connected between a bottom portion of the first protection frame 21′ and a bottom portion of the second protection frame 22′.

For example, referring to FIG. 8, the first auxiliary retaining structure 216A and the second auxiliary retaining structure 226A may be two retaining bodies that can be retainingly mated with each other. When the first protection frame 21′ and the second protection frame 22′ are respectively disposed on two opposite lateral sides of the hand-held electronic device 1, the first auxiliary retaining structure 216A and the second auxiliary retaining structure 226A can be retainingly mated with each other to increase the connection strength between the top portion of the first protection frame 21′ and the top portion of the second protection frame 22′.

For example, referring to FIG. 9, the first auxiliary retaining structure 216B may be a male button, and the second auxiliary retaining structure 226B may be a female retainingly mated with the male button. When the first protection frame 21′ and the second protection frame 22′ are respectively disposed on two opposite lateral sides of the hand-held electronic device 1, the first auxiliary retaining structure 216B and the second auxiliary retaining structure 226B can be retainingly mated with each other to increase the connection strength between the top portion of the first protection frame 21′ and the top portion of the second protection frame 22′.

In conclusion, when the user wants to use the protection structure Z to protect the hand-held electronic device 1, the hand-held electronic device 1 can be placed between the first protection frame 21 and the second protection frame 22 in advance, and then the connection element 30 can be retainingly connected between the first protection frame 21 and the second protection frame 22 by sliding. Hence, the first protection frame 21 and the second protection frame 22 can be respectively positioned on the front surrounding edge 103 and the rear surrounding edge 104 of the hand-held electronic device 1 for protecting the hand-held electronic device 1 through the connection element 30.

The above-mentioned descriptions merely represent the preferred embodiments of the instant disclosure, without any intention or ability to limit the scope of the instant disclosure which is fully described only within the following claims Various equivalent changes, alterations or modifications based on the claims of instant disclosure are all, consequently, viewed as being embraced by the scope of the instant disclosure.

What is claimed is:

1. A protection structure applied to a hand-held electronic device, the hand-held electronic device has a front surface, a rear surface opposite to the front surface, a surrounding peripheral surface disposed between the front surface and the rear surface, a front surrounding edge connected between the front surface and the surrounding peripheral surface, and a rear surrounding edge connected between the rear surface and the surrounding peripheral surface, wherein the protection structure comprises:
a protection unit including at least one first protection frame corresponding to the front surrounding edge of the hand-held electronic device and at least one second protection frame corresponding to the rear surrounding edge of the hand-held electronic device, wherein the hand-held electronic device is placed between the at least one first protection frame and the at least one second protection frame, the at least one first protection frame has at least two first upper retaining structures, and the at least one second protection frame has at least two second upper retaining structures respectively corresponding to the at least two first upper retaining structures; and
a connection unit including at least one connection element slidably disposed between the at least one first protection frame and the at least one second protection frame, wherein the at least one first protection frame and the at least one second protection frame are respectively positioned on the front surrounding edge and the rear surrounding edge of the hand-held electronic device through the at least one connection element, and the at least one connection element has at least two first front retaining structures respectively retainingly mated with the at least two first upper retaining structures and at least two first rear retaining structures respectively retainingly mated with the at least two second upper retaining structures.

2. The protection structure of claim 1, wherein the protection unit includes at least one first surrounding buffer pad disposed between an inner edge of the at least one first protection frame and the front surrounding edge of the hand-held electronic device and at least one second surrounding buffer pad disposed between an inner edge of the at least one second protection frame and the rear surrounding edge of the hand-held electronic device, the at least one first protection frame is separated from the hand-held electronic device by a first predetermined distance through the at least one first surrounding buffer pad, and the at least one second protection frame is separated from the hand-held electronic device by a second predetermined distance through the at least one second surrounding buffer pad.

3. The protection structure of claim 1, wherein each first upper retaining structure is a first retaining block and each first front retaining structure is a front retaining groove for receiving the first retaining block, wherein each second upper retaining structure is a second retaining block and each first rear retaining structure is a rear retaining groove for receiving the second retaining block.

4. The protection structure of claim 1, wherein the at least one first protection frame has at least two first lower retaining structures, the at least one second protection frame has at least two second lower retaining structures respectively corresponding to the at least two first lower retaining structures, and the at least one connection element has at least two second front retaining structures respectively retainingly mated with the at least two first lower retaining structures and at least two second rear retaining structures respectively retainingly mated with the at least two second lower retaining structures.

5. The protection structure of claim 4, wherein the at least two first upper retaining structures are respectively disposed on two opposite lateral sides of the at least one first protection frame, the at least two second upper retaining structures are respectively disposed on two opposite lateral sides of the at least one second protection frame, the at least two first lower retaining structures are disposed on the bottom side of the at least one first protection frame, and the at least two second lower retaining structures are disposed on the bottom side of the at least one second protection frame.

6. The protection structure of claim 1, wherein the at least one first protection frame has at least two first positioning grooves, the at least one second protection frame has at least two second positioning grooves, and the at least one connection element has at least two front positioning protrusions respectively positioned in the at least two first positioning grooves and at least two rear positioning protrusions respectively positioned in the at least two positioning grooves.

7. The protection structure of claim 1, wherein the at least one first protection frame has at least one first left-sided sliding track and at least one first right-sided sliding track, the at least one second protection frame has at least one second left-sided sliding track corresponding to the at least one first left-sided sliding track and at least one second right-sided sliding track corresponding to the at least one first right-sided sliding track, and the at least one connection element has at least one left-sided sliding groove for concurrently receiving the at least one first left-sided sliding track and the at least one second left-sided sliding track and at least one right-sided sliding groove for concurrently receiving the at least one first right-sided sliding track and the at least one second right-sided sliding track.

8. The protection structure of claim 7, wherein the at least one first left-sided sliding track and the at least one second left-sided sliding track are contacted with each other, and the at least one first right-sided sliding track and the at least one second right-sided sliding track are contacted with each other.

9. The protection structure of claim 1, wherein the at least one first protection frame has at least one first auxiliary retaining structure, and the at least one second protection frame has at least one second auxiliary retaining structure retainingly mated with the at least one first auxiliary retaining structure.

10. The protection structure of claim 9, wherein the at least one first auxiliary retaining structure is disposed on a top portion of the at least one first protection frame, the at least one second auxiliary retaining structure is disposed on a top portion of the at least one second protection frame, and the at least one connection element is connected between a bottom portion of the at least one first protection frame and a bottom portion of the at least one second protection frame.

11. The protection structure of claim 1, wherein the protection unit includes at least one pivot structure connected between a top portion of the at least one first protection frame and a top portion of the at least one second protection frame, and the at least one connection element is connected between a bottom portion of the at least one first protection frame and a bottom portion of the at least one second protection frame.

12. The protection structure of claim 1, wherein the at least one connection element is a U-shaped piece, and the at least one connection element has at least one through opening passing through the bottom side thereof for exposing a bottom portion of the hand-held electronic device.

13. A protection structure applied to a hand-held electronic device, comprising:
a protection unit including at least one first protection frame and at least one second protection frame, wherein the hand-held electronic device is placed between the at least one first protection frame and the at least one second protection frame; and
a connection unit including at least one connection element slidably disposed between the at least one first protection frame and the at least one second protection frame, wherein the at least one first protection frame and the at least one second protection frame are positioned on the hand-held electronic device through the at least one connection element.

14. The protection structure of claim 13, wherein the protection unit includes at least one first surrounding buffer pad disposed between an inner edge of the at least one first protection frame and the front surrounding edge of the hand-held electronic device and at least one second surrounding buffer pad disposed between an inner edge of the at least one second protection frame and the rear surrounding edge of the hand-held electronic device, the at least one first protection frame is separated from the hand-held electronic device by a first predetermined distance through the at least one first surrounding buffer pad, and the at least one second protection frame is separated from the hand-held electronic device by a second predetermined distance through the at least one second surrounding buffer pad.

15. The protection structure of claim 13, wherein the at least one first protection frame has at least two first upper retaining structures, the at least one second protection frame has at least two second upper retaining structures respectively corresponding to the at least two first upper retaining structures, and the at least one connection element has at least two first front retaining structures respectively retainingly mated with the at least two first upper retaining structures and at least two first rear retaining structures respectively retainingly mated with the at least two second upper retaining structures.

16. The protection structure of claim 13, wherein the at least one first protection frame has at least two first lower retaining structures, the at least one second protection frame has at least two second lower retaining structures respectively corresponding to the at least two first lower retaining structures, and the at least one connection element has at least two second front retaining structures respectively retainingly mated with the at least two first lower retaining structures and at least two second rear retaining structures respectively retainingly mated with the at least two second lower retaining structures.

17. The protection structure of claim 13, wherein the at least one first protection frame has at least two first positioning grooves, the at least one second protection frame has at least two second positioning grooves, and the at least one connection element has at least two front positioning protrusions respectively positioned in the at least two first positioning grooves and at least two rear positioning protrusions respectively positioned in the at least two positioning grooves.

18. The protection structure of claim 13, wherein the at least one first protection frame has at least one first left-sided sliding track and at least one first right-sided sliding track, the at least one second protection frame has at least one second left-sided sliding track corresponding to the at least one first left-sided sliding track and at least one second right-sided sliding track corresponding to the at least one first right-sided sliding track, and the at least one connection element has at least one left-sided sliding groove for concurrently receiving the at least one first left-sided sliding track and the at least one second left-sided sliding track and at least one right-sided sliding groove for concurrently receiving the at least one first right-sided sliding track and the at least one second right-sided sliding track.

19. The protection structure of claim 13, wherein the at least one first protection frame has at least one first auxiliary retaining structure, and the at least one second protection frame has at least one second auxiliary retaining structure retainingly mated with the at least one first auxiliary retaining structure.

20. The protection structure of claim 13, wherein the protection unit includes at least one pivot structure connected between a top portion of the at least one first protection frame and a top portion of the at least one second protection frame, and the at least one connection element is connected between a bottom portion of the at least one first protection frame and a bottom portion of the at least one second protection frame.
